(19) United States
(12) Patent Application Publication
(10) Pub. No.: US 2014/0027144 A1
(43) Pub. Date: Jan. 30, 2014

(54) PROTECTIVE COVER MODULE FOR CHIP CARD HOLDER

(71) Applicants: Shenzhen Futaihong Precision Industry Co., Ltd., (US); FIH (HONG KONG) LIMITED, Kowloon (HK)

(72) Inventor: LEI HUANG, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/868,362

(22) Filed: Apr. 23, 2013

(30) Foreign Application Priority Data
Jul. 30, 2012 (CN) 2012101360537

(51) Int. Cl. H05K 5/02

(52) U.S. Cl. CPC H05K 5/0239
USPC 174/66

(57) ABSTRACT

A protective cover module is assembled to a portable electronic device. The protective cover module includes a housing, an elastic plate and a pressing element. The housing defines a through hole. The elastic plate is latched on the housing, and the elastic plate defines a slot. The pressing element is magnetically attracted to the elastic plate and covers the through hole.

### BACKGROUND

1. Technical Field

The present disclosure relates to chip card holders, and particularly to a chip card holder with a protective cover module for portable electronic devices.

2. Description of Related Art

With the development of wireless communication and information processing technologies, portable electronic devices such as mobile phones are now widely used. Surface contact cards are necessary elements in portable electronic devices.

Many chip card holders are positioned at one side of the electronic device (e.g. IPHONE™, produced by Apple Company). A hole is exposed for convenient insertion and removal of the surface contact card using a tool. However, the hole in the portable electronic device often affects the device appearance. In addition, tools can be easily lost, and the operation of removing the protective cover can be troublesome.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the exemplary chip card holder with the protective module. Moreover, in the drawings like reference numerals designate corresponding parts throughout the several views. Wherever possible, the same reference numbers are used throughout the drawings to refer to the same or like elements of an embodiment.

FIG. 1 is an exploded view of one embodiment of a chip card holder used in a portable electronic device.

FIG. 2 is an assembled view of the chip card holder, showing a protective cover module in a closed state.

### DETAILED DESCRIPTION

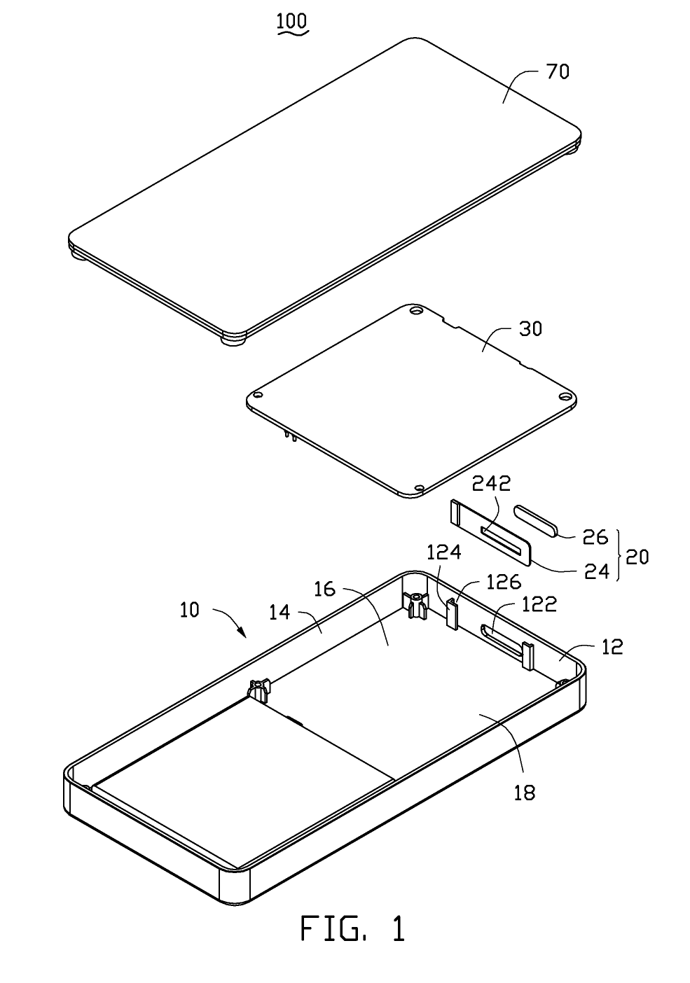

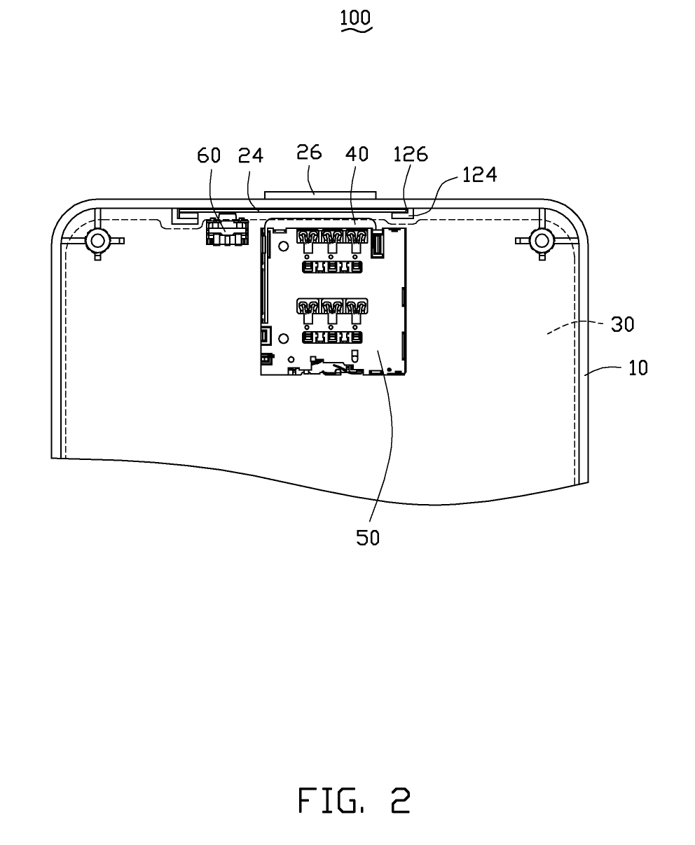

FIGS. 1 to 2 is an exemplary embodiment of a chip card holder. The chip card holder might be used in a portable electronic device 100, such as a cellular phone or any electronic device where a chip card is required. The portable electronic device 100 includes a housing 10, a protective cover module 20, a printed circuit board 30, a chip card holder 50, a key switch 60 and a cover 70. The chip card holder 50 and the key switch 60 are assembled in the housing 10. A chip card (not shown) can be selectively placed in the chip card holder 50. The chip card may be a subscriber identity module (SIM) card or a flash card.

The housing 10 may be a portion of the portable electronic device or a separate element fixed to the portable electronic device. In this exemplary embodiment, The housing 10 includes two opposite end walls 12, two opposite sidewalls 14, and a bottom wall 16 integrally formed together, thereby cooperatively defining a receiving cavity 18. The printed circuit board 30, the chip card holder 50, the key switch 60 are received in the receiving cavity 18. In the exemplary embodiment, one of the end walls 12 defines a through hole 122. An inner surface of the end wall 12 defining the through hole 122 has two L-shaped latching plate 124. Each L-shaped latching plates 124 is at one of the opposite sides of the through hole 122. The vertical part of each L-shaped latching plate 124 perpendicularly extends inward from the inner surface of the end wall 12. The horizontal part of each L-shaped latching plate 124 is parallel with the inner surface of the end wall 12. A latching groove 126 is defined between the two latching plates 124.

The protective cover module 20 includes an elastic plate 24 and a pressing element 26. The elastic plate 24 is made of metal, and is formed by punching into a predetermined shape. The metal material used can be magnetic. The elastic plate 24 is received in the latching groove 126, and opposite ends of the elastic plate 24 are retained by the latching plates 124. The elastic plate 24 defines a longitudinal slot 242. When the elastic plate 24 is latched in the latching groove 126, the slot 242 is aligned with the through hole 122. The pressing element 26 is a bar-shaped magnet, and is configured for being magnetically attracted to the elastic plate 24. A size of the pressing element 26 is substantially the same as the size of the through hole 122, and is larger than the size of the slot 242. The pressing element 26 can be plugged in the through hole 122 for covering the through hole 122, and is magnetically attached on the elastic plate 24.

The chip card holder 50 and the key switch 60 are assembled in the printed circuit board 30, and are adjacent to each other. The key switch 60 is also adjacent to an inside surface of the elastic plate. Therefore, when the elastic plate 24 is latched in the latching groove 126, the key switch 60 faces one part of the elastic plate 24 and the chip card holder 50 is aligned with the slot 242 of the elastic plate 24. In this exemplary embodiment, the key switch 60 functions as a power key.

In use, if the key switch 60 needs to be activated, the pressing element 26 is pressed and the elastic plate 24 can be bent to activate the key switch 60 for turning on the power of the portable electronic device 100. If a chip card 40 needs to be installed in or removed from the chip card holder 50, the pressing element 26 can be removed from the through hole 122 to expose the slot 242. Thus, the chip card can then be easily removed from the tray 30.

As described above, the exemplary embodiment provides a protective cover module 20 not only prevents the chip card holder 50 from being exposed from the electronic device 100, but also controls the key switch 60 to work. The protective cover module 20 integrates two functions, and simplifies the structure of the portable electronic device 100.

Although numerous characteristics and advantages of the exemplary disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A protective cover module assembled to a portable electronic device, the protective cover module comprising:
a housing defining a through hole;
an elastic plate latched on the housing, the elastic plate defining a slot;
a pressing element magnetically attracted to the elastic plate and covering the through hole.

2. The protective cover module of claim 1, wherein the elastic plate is made of a magnetic material, the pressing element is a bar-shaped magnet, and the pressing plate is magnetically attracted to the elastic plate.

3. The protective cover module of claim 1, wherein the housing includes two latching plates at opposite sides of the through hole, opposite ends of the elastic plate are retained by the latching plates.

4. A portable electronic device, comprising:
a housing defining a through hole;
an elastic plate latched on the housing, the elastic plate defining a slot;
a pressing element magnetically attracted to the elastic plate and covering the through hole;
a chip card holder aligned with the slot of the elastic plate and positioned inside the housing.

5. The portable electronic device of claim 4, further comprising a key switch, wherein the key switch faces the elastic plate, and the pressing element is pressed to allow the elastic plate to control the key switch to work.

6. The portable electronic device of claim 4, wherein the elastic plate is made of a magnetic material, the pressing element is a bar-shaped magnet, and the pressing plate is magnetically attracted to the elastic plate.

7. The portable electronic device of claim 6, wherein the housing including two latching plates at opposite sides of the through hole, opposite ends of the elastic plate are retained by the latching plates.
